(19) United States
(12) Patent Application Publication
(10) Pub. No.: US 2009/0189299 A1
(43) Pub. Date: Jul. 30, 2009

(54) METHOD OF FORMING A PROBE PAD LAYOUT/DESIGN, AND RELATED DEVICE

(75) Inventors: Ariel L. Miranda, Daraga (PH); Norihiro Kawakami, Beppu (JP); Charles A. Odegard, McKinney, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/022,438

(22) Filed: Jan. 30, 2008

(51) Int. Cl. H01L 21/66; H01L 23/52

(52) U.S. Cl. 257/782; 438/17; 257/E21.531; 257/E23.141

(57) ABSTRACT

A method of forming a probe pad layout/design, and related device. At least some of the illustrative embodiments are methods comprising testing a semiconductor device by electrically contacting a first portion of a semiconductor die by way of a first pad within a scribe street adjacent to the semiconductor die, and electrically contacting a second portion of the semiconductor die by way of a first bond pad within the semiconductor die.

### BACKGROUND

Electronic devices are continually getting smaller, faster, and using less power, while simultaneously being able to support and perform a greater number of increasingly complex and sophisticated functions. One reason for these trends is an ever increasing demand for small, portable and multifunctional electronic devices. For example, cellular phones, personal computing devices, and personal audio devices (e.g., MP3 players) are in great demand in the consumer market. Such electronic devices rely on a limited power source (e.g., batteries) while providing ever-increasing processing capabilities and storage capacity.

Accordingly, there is a continuing trend in the semiconductor industry to manufacture low-cost, high-performance, and low-power integrated circuits (ICs). IC manufacturing involves a series of processing steps such as transistor fabrication, fabrication of interconnect layers, testing to check for defects in the IC (e.g., die probing at bond pads), and packaging of individual die (i.e., “chips”). As IC design and manufacturing techniques improve, shrinking die sizes introduce many new complexities including problems associated with die probing and packaging. Accordingly, probing and packaging technology should meet the demands imposed by the continued advances in IC design and manufacturing.

### SUMMARY

The problems noted above are solved in large part by a method of forming a probe pad layout/design, and related device. At least some of the illustrative embodiments are methods comprising testing a semiconductor device by electrically contacting a first portion of a semiconductor die by way of a first pad within a scribe street adjacent to the semiconductor die, and electrically contacting a second portion of the semiconductor die by way of a first bond pad within the semiconductor die.

Other illustrative embodiments are semiconductor devices constructed by a method comprising forming a first bond pad within a semiconductor die, forming a first pad within a scribe street adjacent to the semiconductor die, and coupling the first pad to the first bond pad.

Yet other illustrative embodiments are semiconductor devices comprising a first die comprising a first bond pad, a scribe street adjacent to the first die comprising a first pad, and an interconnect that couples the first pad to the first bond pad.

### BRIEF DESCRIPTION OF THE DRAWINGS

For a more detailed description of the various embodiments, reference will now be made to the accompanying drawings, wherein:

FIG. 1 shows a semiconductor wafer comprising a plurality of die;

FIG. 2 shows an enlarged view of some of the die;

FIG. 3 shows an enlarged view of portions of two neighboring die according to some embodiments;

FIG. 4 shows an enlarged view of portions of two neighboring die where a bond pad pitch is less than a probe pitch;

FIG. 5 shows an enlarged view of portions of two neighboring die having an adjacent scribe street comprising pads that are coupled to bond pads within the die;

FIG. 6 shows an enlarged view of portions of two neighboring die having an adjacent scribe street comprising pads according to some alternative embodiments;

FIG. 7 shows an exemplary flow diagram according to various embodiments; and

FIG. 8 shows an exemplary flow diagram for constructing a semiconductor device according to various embodiments.

### NOTATION AND NOMENCLATURE

Certain terms are used throughout the following description and claims to refer to particular system components. As one skilled in the art will appreciate, various companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the term “couple” or “couples” is intended to mean either an indirect or direct connection. Thus, if a first device couples to a second device, that connection may be through a direct connection, or through an indirect connection via other devices and connections.

Unless otherwise stated, when a layer is said to be “deposited over” or “formed over”, it means that the layer is deposited or formed over any topography that already exists on the substrate.

### DETAILED DESCRIPTION

The following discussion is directed to various embodiments. Although one or more of these embodiments may be preferred, the embodiments disclosed should not be interpreted, or otherwise used, as limiting the scope of the disclosure, including the claims, unless otherwise specified. In addition, one skilled in the art will understand that the following description has broad application, and the discussion of any embodiment is meant only to be exemplary of that embodiment, and not intended to intimate that the scope of the disclosure, including the claims, is limited to that embodiment. Also, layers and/or elements depicted herein are illustrated with particular dimensions and/or orientations relative to one another for purposes of simplicity and ease of understanding, and actual dimensions and/or orientations of the layers and/or elements may differ substantially from that illustrated herein.

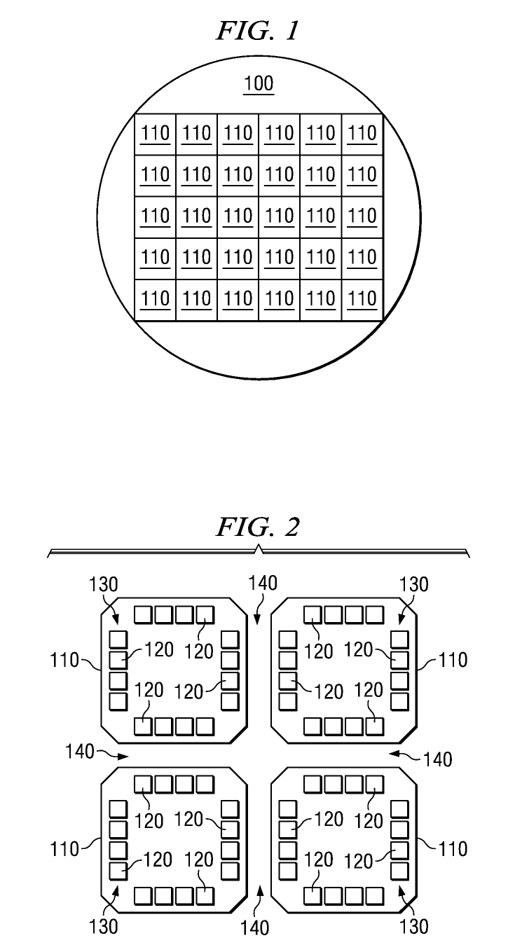

The subject matter disclosed herein is directed to methods and related systems associated with construction of a semiconductor device that utilizes a probe pad design/layout for testing (i.e., probing) of die on a semiconductor wafer. FIG. 1 illustrates an example of a semiconductor wafer 100 comprising a plurality of semiconductor die 110. Each of the plurality of semiconductor die 110 is delineated from another of the plurality of semiconductor die 110 at least partially by way of a scribe street (discussed below). For purposes of this disclosure, each one of the plurality of semiconductor die 110, as illustrated in FIG. 1 as an integral part of the semiconductor wafer 100, may be referred to as a semiconductor die 100 or as a die 110. Prior to packaging of the die 110, each of the plurality of die 110 is tested (i.e., probed) for functionality and performance via bond pads (discussed below). FIG. 2 illustrates an enlarged view of some of the die 110 of the semiconductor wafer 100 (FIG. 1) showing bond pads 120 on each of the plurality of die 110. The bond pads 120 form a pad ring 130 disposed along a periphery of each of the plurality of die 110. Each bond pad 120 is electrically coupled to an underlying input/output (I/O) cell that provides electrical communication to various portions of the die 110. FIG. 2 also illustrates a region between each of the plurality of die 100 that is referred to as a scribe street 140. The scribe street 140 may comprise alignment marks used to align different masking levels used during photolithographic processes. The scribe street 140 may also comprise test structures used to test functionality of specific device types or to collect process control data. After probing each of the plurality of die 110 for functionality and performance, each of the die 110 are physically separated from each other by performing a wafer dicing process in the scribe street 140. The wafer dicing process can be performed by various methods such as scribing and breaking, mechanical sawing, or by laser cutting. The wafer dicing process thus destroys any structures within the scribe street 140. However, as the scribe street 140 is not part of the die 110, the wafer dicing process does not damage circuits and/or components formed within each of the die 110. After the dicing process is complete, each of the individual die 110 is packaged.

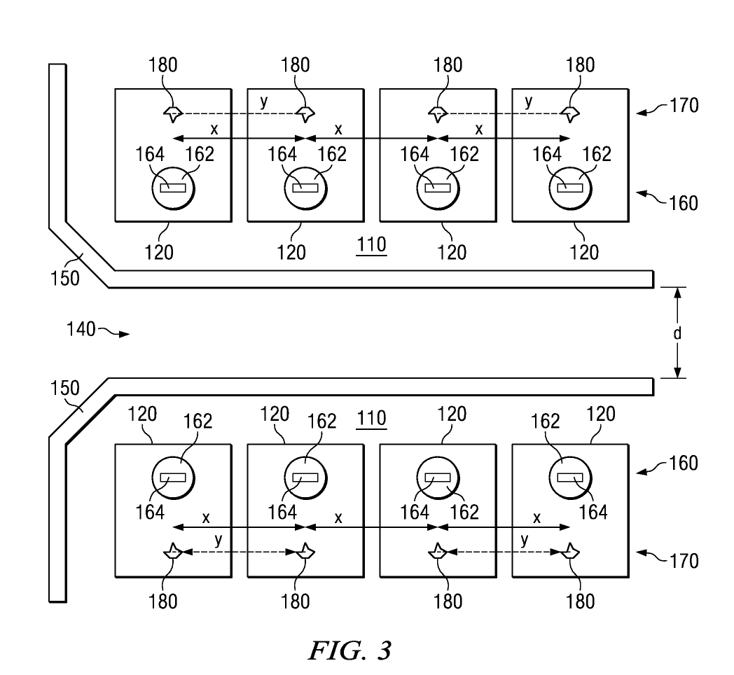

FIG. 3 illustrates an enlarged view of portions of two neighboring die 110 separated by the scribe street 140. A scribe seal 150 defines a border of each of the die 110. The scribe seal 150 may comprise a conductive material (e.g., a top layer metal such as aluminum). In some embodiments, a distance “d” between neighboring die 110 (i.e., a width of the scribe street 140) is less than or equal to about 62 microns. FIG. 3 also shows the bond pads 120 in more detail. As shown, the bond pads 120 comprise a bond area 160, where electrical contact is made to the die 110 (e.g., by way of wire bonding or depositing a stud bump to be used in a flip chip packaging configuration), and a probe area 170, where in-line electrical testing is performed. The bond area 160 comprises a contact location 162 (e.g., where a wire bond or stud bump will be placed after electrical testing) and a via 164 that electrically couples the bond pad 120 to an underlying metal layer comprising the I/O cell. For embodiments as described herein, placement of the contact location 162 within a specific area of the bond pad 120 is not critical. In some embodiments, the contact location 162 is only partially over the via 164. In other embodiments, the contact location 162 is away from the via 164. In yet other embodiments, the contact location 162 is within the probe area 170. Thus, bonding (e.g., by way of a wire bond or stud bump) can be completed over the via 164, partially over the via 164, or away from the via 164. In some embodiments, the bond pads 120 need not comprise the bond area 160 (e.g., when the bond pad 120 is solely used for probing). In other embodiments, the bond pads 120 need not comprise the probe area 170 (e.g., when the bond pad 120 is solely used for making electrical contact to the die 110 or when the bond pad 120 is probed by way of a pad within the scribe street 140, as discussed below).

During in-line probing of the die 100, a test probe (i.e., a prober) makes contact to the die 100 by way of the bond pads 120. In particular, the prober comprises a plurality of probe tips (e.g., where the probe tips comprise conductive needles) that each contact an individual bond pad 120. Probe marks 180 result from physical contact between a probe tip and a bond pad 120 during in-line probing. For purposes of this disclosure, adjacent probe tips may be equivalently referred to as a pair of probe tips, and the bond pads 120 contacted by each pair of probe tips is indicated by a dashed line connecting the probe marks 180. The location of the probe marks 180, and the dashed lines, show that adjacent probe tip contact locations are aligned horizontally and are each within the probe area 170 of each of the bond pads 120. Thus, each pair of probe tips contacts the bond pads 120 in a horizontally aligned manner within the probe area 170. In some embodiments, the prober contacts a plurality of bond pads 120 simultaneously by way of the plurality of probe tips. For example, in some embodiments, the prober contacts eight (8) bond pads 120 simultaneously by way of the plurality of probe tips. The distance between two adjacent probe tip contact locations (i.e., the distance between a pair of probe tips, as indicated by the dashed lines) is referred to as a probe pitch “y”. In some embodiments, the probe pitch y is greater than or equal to about 60 microns. Likewise, FIG. 3 illustrates a bond pad pitch “x” as the distance between centers of two adjacent bond pads 120. In some embodiments, such as shown in FIG. 3, where the bond pad pitch x is greater than or about equal to the probe pitch y (e.g., greater than or about equal to about 60 microns), adjacent bond pads 120 can each be probed within the probe area 170, where the probe tip contact locations are horizontally aligned.

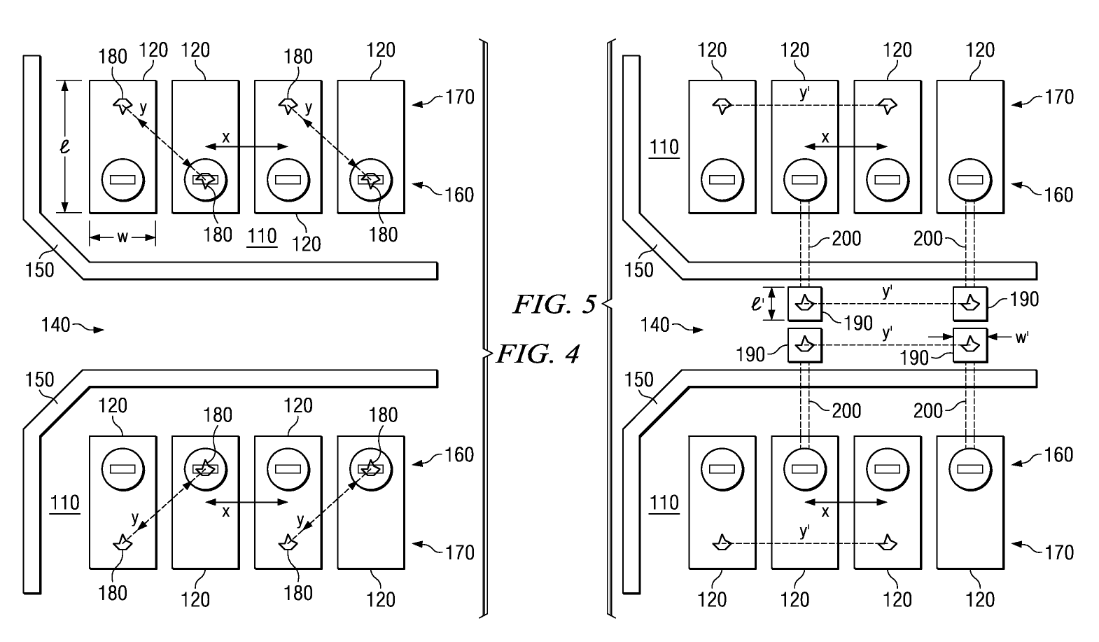

As integrated circuits (IC) and die continue to scale down in size, there is a corresponding reduction in the size of the bond pads 120 and the bond pad pitch x (e.g., to values less than about 60 microns). For example, in some embodiments, the bond pad pitch x is between about 40 microns and 50 microns. However, the probe pitch y does not scale down together with the bond pad pitch x due to limitations in probing technology, and the probe pitch y is thus greater than the bond pad pitch x (e.g., the probe pitch y remains about 60 microns). FIG. 4 illustrates embodiments where the bond pad pitch x is less than the probe pitch y. In some embodiments, a width “w” of the bond pad 120 is less than or equal to about 48 microns, and a length “l” of the bond pad 120 is between about 48 microns and about 100 microns. Instead of probing adjacent bond pads 120 each within the probe area 170 in a horizontally aligned manner, adjacent bond pads 120 are probed within either the probe area 170 or the bond area 160. Thus, each pair of probe tips is aligned diagonally, and the probe pitch y is measured diagonally from the probe area 170 of one bond pad 120 to the bond area 160 of the adjacent bond pad 120. Such a probing configuration allows for the continued use of probers having a probe pitch y that is greater than the bond pad pitch x (e.g., at least about 60 microns), with ultra-fine pitch IC technology (i.e., die 110 having a bond pad pitch x of less than about 60 microns or die 110 having a bond pad pitch x that is less than the probe pitch y). However, there are shortcomings to this approach. In particular, probing on the bond area 160 can damage the contact location 162. Damage to an inter-layer dielectric (e.g., an ultra low-k material that reduces parasitic capacitance between metal layers) caused by probing on the bond area 160 degrades reliability of the die 110. Moreover, damage to the contact location 162 makes it difficult to make electrical contact to the bond pad 120 (e.g., by way of a wire bond or stud bump) due to an increased risk of metal lifting (e.g., because of poor adhesion) caused by the damage. The various embodiments described herein provide a method, and related structure, where additional probe areas are provided within the scribe street 140, and the bond area 160 is no longer probed. Thus, the various embodiments maintain the reliability of the contact locations 162 and allow for the reliable, continued use of in-line probers having a probe pitch y that is greater than the bond pad pitch x.

FIG. 5 shows an enlarged view of portions of two neighboring die 110 separated by the scribe street 140, where the scribe street 140 comprises pads 190. In some embodiments, a width “w′” of the pad 190 is between about 20 microns and about 60 microns, a length “l′” of the pad 190 is between about 20 microns and about 60 microns. There is also at least about a one (1) micron separation between each of the pads 190. The pads 190 are coupled to the bond pads 120 by way of an interconnect 200. Thus, rather than probing on the bond area 160, the pads 190 provide an alternative probing location within the scribe street 140. There are various ways to form the interconnect 200. In some embodiments, there is a discontinuity in the scribe seal 150, where the interconnect 200 passes through the discontinuity to electrically couple the bond pad 120 to the pad 190. In alternative embodiments, after formation of the scribe seal 150, a layer of passivation (e.g., SiON or SiN) is deposited over the scribe seal 150, and the interconnect 200 is deposited over the passivation layer to electrically couple the bond pad 120 to the pad 190. In each of the various embodiments of forming the interconnect 200, there is a passivation layer or inter-layer dielectric that electrically isolates the scribe seal 150 from the interconnect 200. In some embodiments, both the interconnect 200 and the scribe seal 150 comprise a top layer metal (e.g., aluminum). In other embodiments, the interconnect 200 comprises a metal layer underlying the top metal layer.

The bond pad pitch x as shown in FIG. 5 is illustratively less than about 60 microns (e.g., between about 40 microns to about 50 microns). However, with the pads 190 in the scribe street 140, an alternative probing configuration is used. In particular, an enlarged probe pitch y′ is used, where the probe pitch y′ is greater than the bond pad pitch x. In some embodiments, the probe pitch y′ is between about 80 microns and about 100 microns (i.e., about double the bond pad pitch x). Using the probe pitch y′, each pair of probe tips (as indicated by the dashed lines) is aligned horizontally and contacts every other bond pad 120, either within the probe area 170, or on the pads 190 within the scribe street 140. Thus, every bond pad 120 is probed (either directly or by way of the pads 190) without having to probe on the bond area 160. Such a probing configuration removes probe pitch restrictions imposed by the technology of the in-line prober, is fully compatible with ultra-fine pitch IC technology, and protects the bond area 160 from potential damage caused by in-line probing.

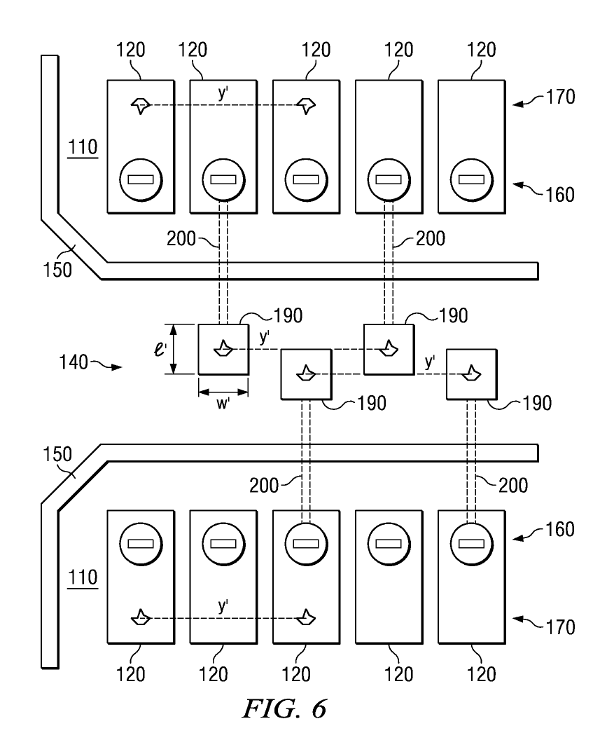

FIG. 6 shows the scribe street 140 comprising the pads 190 in an alternative configuration. In the illustrative embodiments of FIG. 6, the width w′ of the pad 190 is between about 20 microns and about 60 microns, and the length l′ of the pad 190 is between about 20 microns and about 60 microns. Larger pads (compared to FIG. 5) simplify in-line probing and reduce probing errors (e.g., that may result from prober misalignment). The larger pads 190 may be used when there is available space in the scribe street 140 (which is dependent on any existing test structures or alignment marks in the scribe street 140). In other embodiments, use of the larger pads is dependent on the in-line prober technology (e.g., when using a prober that has large probe tips).

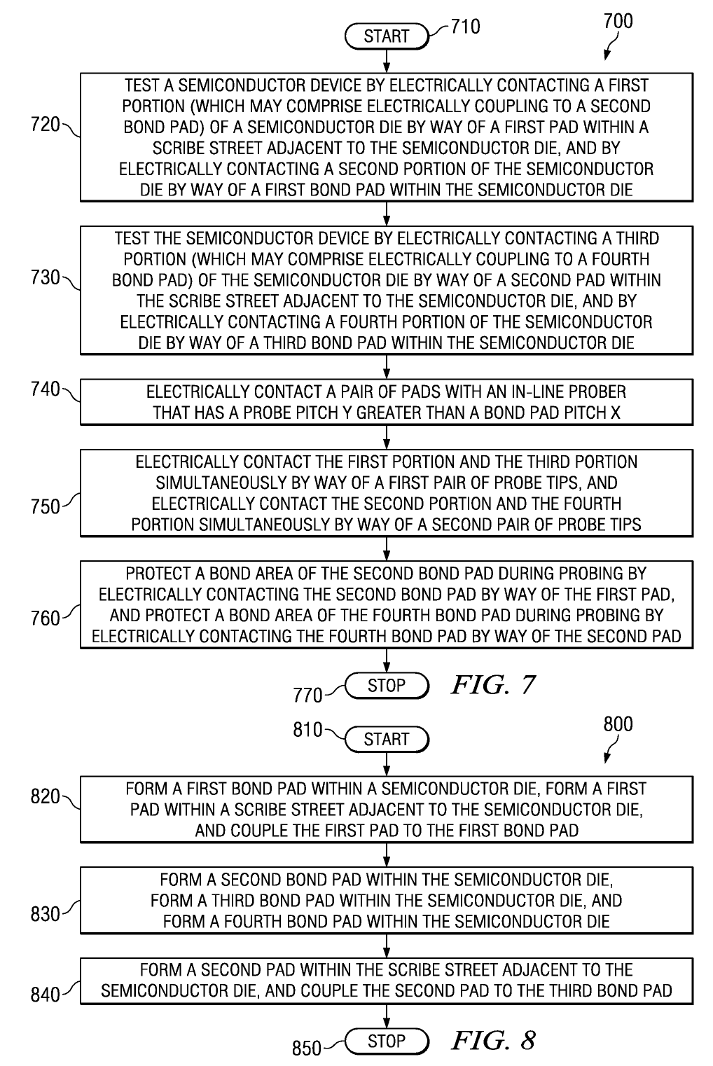

FIG. 7 shows an exemplary flow diagram 700 according to various embodiments. The method starts (block 710) and proceeds to testing a semiconductor device by electrically contacting a first portion of a semiconductor die by way of a first pad within a scribe street adjacent to the semiconductor die, and by electrically contacting a second portion of the semiconductor die by way of a first bond pad within the semiconductor die (block 720). In some embodiments, electrically contacting the first portion may comprise electrically coupling to a second bond pad. Thereafter, the method proceeds to proceeds to testing the semiconductor device by electrically contacting a third portion of the semiconductor die by way of a second pad within the scribe street adjacent to the semiconductor die, and by electrically contacting a fourth portion of the semiconductor die by way of a third bond pad within the semiconductor die (block 730). In some embodiments, electrically contacting the third portion may comprise electrically coupling to a fourth bond pad. Pairs of pads are electrically contacted with an in-line prober that has a probe pitch y that is greater than a bond pad pitch x (block 740). The first portion and the third portion are electrically contacted simultaneously by way of a first pair of probe tips, and the second portion and the fourth portion are electrically contacted simultaneously by way of a second pair of probe tips (block 750). During probing, a bond area of the second bond pad is protected by electrically contacting the second bond pad by way of the first pad, and a bond area of the fourth bond pad is protected by electrically contacting the fourth bond pad by way of the second pad (block 760). The method then ends (block 770).

FIG. 8 shows an exemplary flow diagram 800 for constructing a semiconductor device according to various embodiments. The method starts (810) and proceeds to forming a first bond pad within a semiconductor die, forming a first pad within a scribe street adjacent to the semiconductor die, and coupling the first pad to the first bond pad (block 820). Thereafter, a second bond pad is formed within the semiconductor die, a third bond pad is formed within the semiconductor die, and a fourth bond pad is formed within the semiconductor die (block 830). A second pad is then formed within the scribe street adjacent to the semiconductor die, and the second pad is coupled to the third bond pad (block 840). The method then ends (block 850).

The above discussion is meant to be illustrative of the principles and various embodiments of the present invention. Numerous variations and modifications will become apparent to those skilled in the art once the above disclosure is fully appreciated. For example, unless otherwise indicated, any one or more of the layers set forth herein can be formed in any number of suitable ways (e.g., with spin-on techniques, sputtering techniques (e.g., magnetron and/or ion beam sputtering), thermal growth techniques, deposition techniques such as chemical vapor deposition (CVD), physical vapor deposition (PVD) and/or plasma enhanced chemical vapor deposition (PECVD), or atomic layer deposition (ALD)). And, unless otherwise indicated, any one or more of the layers can be patterned in any suitable manner (e.g., via lithographic and/or etching techniques). It is intended that the following claims be interpreted to embrace all such variations and modifications.

What is claimed is:

1. A method comprising:
testing a semiconductor device by:
electrically contacting a first portion of a semiconductor die by way of a first pad within a scribe street adjacent to the semiconductor die; and
electrically contacting a second portion of the semiconductor die by way of a first bond pad within the semiconductor die.

2. The method according to claim 1 wherein electrically contacting the first portion further comprises electrically coupling to a second bond pad within the semiconductor die by way of the first pad within the scribe street.

3. The method according to claim 1 further comprising:
electrically contacting a third portion of the semiconductor die by way of a second pad within the scribe street adjacent to the semiconductor die; and
electrically contacting a fourth portion of the semiconductor die by way of a third bond pad within the semiconductor die.

4. The method according to claim 3 wherein electrically contacting the third portion further comprises electrically coupling to a fourth bond pad within the semiconductor die by way of the second pad within the scribe street.

5. The method according to claim 3 further comprising electrically contacting the first portion and electrically contacting the third portion simultaneously by way of a first pair of probe tips.

6. The method according to claim 3 further comprising electrically contacting the second portion and electrically contacting the fourth portion simultaneously by way of a second pair of probe tips.

7. The method of according to claim 3 further comprising electrically contacting a pair of pads with an in-line prober that has a probe pitch “y” that is greater than a bond pad pitch “x”.

8. The method according to claim 2 further comprising protecting a bond area of the second bond pad during probing by electrically contacting the second bond pad by way of the first pad.

9. The method according to claim 4 further comprising protecting a bond area of the fourth bond pad during probing by electrically contacting the fourth bond pad by way of the second pad.

10. A semiconductor device constructed by a method comprising:
forming a first bond pad within a semiconductor die;
forming a first pad within a scribe street adjacent to the semiconductor die; and
coupling the first pad to the first bond pad.

11. The semiconductor device constructed by the method according to claim 10 further comprising:
forming a second bond pad within the semiconductor die;
forming a third bond pad within the semiconductor die; and
forming a fourth bond pad within the semiconductor die.

12. The semiconductor device constructed by the method according to claim 11 further comprising:
forming a second pad within the scribe street adjacent to the semiconductor die; and
coupling the second pad to the third bond pad.

13. A semiconductor device comprising:
a first die comprising a first bond pad;
a scribe street adjacent to the first die comprising a first pad; and
an interconnect that couples the first pad to the first bond pad.

14. The semiconductor device according to claim 13 further comprising a first scribe seal that defines a border of the first die and a second scribe seal that defines a border of a second die, wherein a distance between the first scribe seal and the second scribe seal is less than or equal to about 62 microns.

15. The semiconductor device according to claim 13 wherein the first bond pad further comprises one or more selected from the group consisting of: a bond area, and a probe area.

16. The semiconductor device according to claim 13 wherein the first bond pad has a width of less than or equal to about 48 microns, and wherein the first bond pad has a length of between about 48 microns and about 100 microns.

17. The semiconductor device according to claim 13 wherein the first pad has a width of between about 20 microns and about 60 microns, and wherein the first pad has a length of between about 20 microns and about 60 microns.

18. The semiconductor device according to claim 13 wherein the first die comprises a second bond pad adjacent to the first bond pad, wherein a bond pad pitch ‘x’ is a distance between centers of the first bond pad and the second bond pad, and wherein the bond pad pitch ‘x’ is less than a probe pitch ‘y’.

19. The semiconductor device according to claim 18 wherein the bond pad pitch ‘x’ is between about 40 microns and about 50 microns.

20. The semiconductor device according to claim 18 wherein the probe pitch ‘y’ is between about 80 microns and about 100 microns.
